(19) United States
(12) Patent Application Publication
(10) Pub. No.: US 2018/0108780 A1
(43) Pub. Date: Apr. 19, 2018

(54) THIN FILM TRANSISTOR AND MANUFACTURE METHOD THEREOF

(71) Applicant: Shenzhen China Star Optoelectronics Technology Co.,Ltd., Shenzhen, Guangdong (JP)

(72) Inventor: Jinming LI, Shenzhen, Guangdong (CN)

(73) Assignee: Shenzhen China Star Optoelectronics Technology Co., Ltd., Shenzhen, Guangdong (CN)

(21) Appl. No.: 15/111,780

(22) PCT Filed: May 12, 2016
(86) PCT No.: PCT/CN2016/081784

§ 371 Date: Jul. 14, 2016

(30) Foreign Application Priority Data
Mar. 10, 2016 (CN) 201610135630.9

(51) Int. Cl. H01L 29/786; H01L 29/66; H01L 27/12

(52) U.S. Cl. CPC H01L 29/7869; H01L 27/1225; H01L 29/66969

(57) ABSTRACT

The disclosure provides a thin film transistor (TFT) and a manufacture method thereof. The TFT includes: a substrate; a gate electrode, formed on the substrate; a gate insulating layer, formed on the gate electrode; a semiconductor layer, formed on the gate insulating layer and corresponding to the gate electrode; a pixel electrode, disposed on the same layer with the semiconductor layer; an ohmic contact layer, formed on the same layer with the semiconductor layer and formed on the same layer with the pixel electrode; a source electrode and a drain electrode, disposed on the ohmic contact layer. According to the TFT and the manufacture method thereof of the exemplary embodiments of the disclosure, the pixel electrode and the semiconductor layer are formed on the same layer, the semiconductor layer and the pixel electrode can be produced by only one mask, which can reduce mask consumption and processes.

### BACKGROUND OF THE INVENTION

### 1. Field Of The Disclosure

The disclosure relates to a semiconductor device technical field, and more particularly to a thin film transistor and a method of manufacturing the thin film transistor.

### 2. The Related Arts

A demand for various electronic devices such as a display device is increasing along with the development of information technology. A thin film transistor (TFT) can be applied as a switch or a driving element in sorts of electronic devices, for instance, a liquid crystal display (LCD), an organic light-emitting diode (OLED) display, a plasma display (PD), an electrophoretic display device (EPD) and an electro wetting display (EWD).

In a conventional TFT, a gate electrode is disposed on a substrate, a gate insulating layer is formed on the gate electrode, a source electrode, a drain electrode, a semiconductor layer and a pixel electrode layer are disposed above the gate insulating layer, the pixel electrode and the drain electrode are connected by a through-hole. Generally, multiple masks and complicated processes are necessary to form each layer in the TFT. Therefore, efficiency for manufacturing the TFT is low and costs are considerable.

The previous information disclosed in the background is merely for enhancing comprehensibility of the background of the disclosure, therefore, it is possible that unknown technical information to a person skilled in the art can be included.

### SUMMARY OF THE DISCLOSURE

Exemplary embodiments provide a TFT of a pixel electrode formed by being irradiated by light with a predetermined wavelength.

Exemplary embodiments provide a manufacture method of a TFT that can reduce processes and mask consumption.

The disclosure provides a thin film transistor, the thin film transistor includes: a substrate; a gate electrode, formed on the substrate; a gate insulating layer, formed on the gate electrode; a semiconductor layer, formed on the gate insulating layer and corresponding to the gate electrode; a pixel electrode, disposed on the same layer with the semiconductor layer; an ohmic contact layer, formed on the same layer with the semiconductor layer and formed on the same layer with the pixel electrode; a source electrode and a drain electrode, disposed on the ohmic contact layer.

According to an exemplary embodiment of the disclosure, the pixel electrode and the drain electrode can be connected by the ohmic contact layer below the drain electrode.

According to an exemplary embodiment of the disclosure, the ohmic contact layer below the drain electrode and the semiconductor layer can be connected.

According to an exemplary embodiment of the disclosure, the gate electrode can be formed by metal and/or metal alloy, the semiconductor layer can be formed by oxide semiconductor.

According to an exemplary embodiment of the disclosure, the thin film transistor can further include a passivation layer. The passivation layer can cover the source electrode, the drain electrode, the semiconductor layer and the pixel electrode.

The disclosure further provides a method of manufacturing a thin film transistor, the method includes: forming a gate electrode on a substrate; forming a gate insulating layer on the gate electrode; forming a semiconductor layer on the gate insulating layer; irradiating light with a predetermined wavelength from the back, making a section of the semiconductor layer that is not covered by the gate electrode to be a pixel electrode and an ohmic contact layer, and a section of the semiconductor layer covered by the gate electrode retains a semiconductor characteristic; forming a source electrode and a drain electrode on the pixel electrode and the ohmic contact layer.

According to an exemplary embodiment of the disclosure, a range of the predetermined wavelength is 110 nm˜760 nm.

According to an exemplary embodiment of the disclosure, the light is ultraviolet light.

According to an exemplary embodiment of the disclosure, the gate electrode is formed by metal and/or metal alloy, the semiconductor layer is formed by oxide semiconductor.

According to an exemplary embodiment of the disclosure, the pixel electrode and the drain electrode are connected by the ohmic contact layer below the drain electrode.

According to an exemplary embodiment of the disclosure, the ohmic contact layer below the drain electrode and the semiconductor layer are connected.

According to an exemplary embodiment of the disclosure, the method can further include forming a passivation layer, to cover the source electrode, the drain electrode, the semiconductor layer and the pixel electrode.

According to the TFT and the manufacture method thereof of the exemplary embodiments of the disclosure, the pixel electrode and the semiconductor layer are formed on the same layer, compared with a conventional technique that two separate masks are needed to form a semiconductor layer and a pixel electrode respectively, the disclosure employs one mask to produce the semiconductor layer and the pixel electrode, which can reduce mask consumption and processes.

### BRIEF DESCRIPTION OF THE DRAWINGS

FIG. 1 is a schematic, cross-sectional view of a TFT according to an exemplary embodiment of the disclosure.

FIG. 2 through FIG. 7 are schematic, cross-sectional views of a method of manufacturing a TFT according to an exemplary embodiment of the disclosure.

### DETAILED DESCRIPTION OF PREFERRED EMBODIMENTS

Embodiments of the disclosure are described in detail with reference to the accompanying drawings as follows. It is clear that all other embodiments obtained by a person skilled in the art without creative efforts should be considered within the scope of protection of the disclosure.

In figures, for the purpose of clear illustration, sizes and relative sizes of layers, films, plates and regions can be exaggerated. Moreover, the same label in the figures always represents the same element.

When an element or a layer is said to be “on”, “connected to” or “combined” another element or layer, the element or layer can be on, connected to or combined another element or layer directly, or an intermediate element or layer can exist. However, when an element or layer is said to be “directly on”, “directly connected to” or “directly combined” another element or layer, no intermediate element or layer exists. The terminology used herein that “and/or” includes any or all possible combinations of one or more of the associated listed items.

For the purpose of description, spatial relative terminology can be used, such as “under”, “below”, “beneath”, “above” and “on”, to describe relation of an element or feature shown in the figures compared with other elements or features. The spatial relative terminology means to include various directions of a device in utilization or operation besides the directions described in the figures. For instance, if a device in a figure is overturned, then an element “under” or “below” another element will be “on” or “above” another element. Therefore, exemplary terminology “below” can include “above” and “below”. Moreover, the device can be re-orientated (i.e. rotating through 90 degrees or other degrees), thereby the spatial relative terminology used here is explained.

The terminology used here is for describing a specific embodiment rather than restriction. Moreover, when “include” and/or “comprise” is used in the disclosure, it means the feature, step, operation, element and/or module exist, with possibility of existing one or more of other features, steps, operations, elements and/or modules.

Unless other definitions are mentioned, all the terminology (including technical terminology and scientific terminology) used here has the meaning known by a person skilled in the art. Unless a clear definition is mentioned, the terminology (as defined in a dictionary) should be explained to have the same meaning in the related art, instead of illustrating ideally or over formally.

FIG. 1 shows a cross-sectional view of a TFT according to an exemplary embodiment of the disclosure.

Referring to FIG. 1, a TFT according to the exemplary embodiment of the disclosure can include: a substrate 1; a gate electrode 2, formed on the substrate 1; a gate insulating layer 3, formed on the gate electrode 2; a semiconductor layer 4, formed on the gate insulating layer 3 and corresponding to the gate electrode 2; a pixel electrode 5, disposed on the same layer with the semiconductor layer 4; ohmic contact layers 9, formed on the same layer with the semiconductor layer 4 and formed on the same layer with the pixel electrode 5; a source electrode 6 and a drain electrode 7, disposed on the ohmic contact layers 9.

According to the exemplary embodiment of the disclosure, the gate electrode 2 can be disposed on the substrate 1 for example made out of plastic or glass. The substrate 1 can be rigid or flexible. The gate electrode 2 can be formed by metal and/or metal alloy. For instance, the gate electrode 2 can be made out of metal based on aluminum (i.e. aluminum (Al) or Al alloy), metal based on silver (i.e. silver (Ag) or Ag alloy), metal based on copper (i.e. copper (Cu) or Cu alloy), metal based on molybdenum (i.e. molybdenum (Mo) or Mo alloy), metal based on chromium (i.e. chromium (Cr) or Cr alloy), metal based on tantalum (i.e. tantalum (Ta) or Ta alloy), metal based on titanium (i.e. titanium (Ti) or Ti alloy). Optionally, the gate electrode 2 can include a multilayer structure, such as at least two conductive layers with different physical properties. For instance, the gate electrode 2 can be a multilayer structure of Mo/Al/Mo, Mo/Al, Mo/Cu, CuMn/Cu and Ti/Cu.

According to the exemplary embodiment of the disclosure, the gate electrode 2 can be formed by a proper process, for instance, physical vapor deposition (PVD) or chemical vapor deposition (CVD). The gate electrode 2 can have a pattern for example formed by a photo process or an etching process. Optionally, a buffer layer (not labelled) can be formed on the substrate 1, and the gate electrode 2 can be formed on the buffer layer. The buffer layer can be skipped according to requirements. A thickness of the gate electrode 2 can be in a range of 2000˜5500 angstroms.

The gate insulating layer 3 can be disposed on the gate electrode 2 to cover the gate electrode 2. The gate insulating layer 3 can be a single-layer or multilayer structure including any proper insulating material such as silicon oxide (SiOₓ), silicon nitride (SiNₓ), silicon oxynitride (SiON). The gate insulating layer 3 can be formed by any proper manner such as plasma enhanced chemical vapor deposition (PECVD). A thickness of the gate insulating layer 3 can be in a range of 1500˜4000 angstroms.

The semiconductor layer 4 can be formed on the gate insulating layer 3, a position of the semiconductor layer 4 can correspond to that of the gate electrode 2. For instance, the semiconductor layer 4 can be formed by oxide semiconductor. For instance, oxide semiconductor can include any proper metal (i.e. zinc (Zn), indium (In), gallium (Ga), tin (Sn), titanium (Ti)) or any proper metal alloy oxide. Optionally, the semiconductor layer 4 can be formed by indium gallium zinc oxide (IGZO). A thickness of the semiconductor layer 4 can be in a range of 400˜1500 angstroms.

The semiconductor layer 4 can be formed by any proper method such as PVD. The semiconductor layer 4 can have a pattern for example formed by a photo process or an etching process. The semiconductor layer 4 can have a pattern insulating from the source electrode 6 to be formed and connected to the drain electrode 7 to be formed by patterning, therefore, it is unnecessary to connect the pixel electrode 5 and the source electrode 6 by a through-hole.

As shown in FIG. 1, the pixel electrode 5 can be formed on the same layer with the semiconductor layer 4, and can be formed on the same layer with the ohmic contact layers 9. The ohmic contact layers 9 can be formed on the same layer with the semiconductor layer 4 and the pixel electrode 5.

According to the exemplary embodiment of the disclosure, the source electrode 6 and the drain electrode 7 can be formed on the ohmic contact layers 9. As shown in FIG. 1, the source electrode 6 and the drain electrode 7 can be formed on the ohmic contact layers 9 adjacent to two ends of the semiconductor layer 4. For instance, the source electrode 6 can be formed on the ohmic contact layer 9 on left side of the semiconductor layer 4, the drain electrode 7 can be formed on the ohmic contact layer 9 on right side of the semiconductor layer 4. The pixel electrode 5 can be connected to the drain electrode 7 by the ohmic contact layer 9 below the drain electrode 7. The ohmic contact layer 9 below the drain electrode 7 can be connected to the semiconductor layer 4. The pixel electrode 5 and the source electrode 6 can be insulated.

Though the source electrode 6 is on the left side and the drain electrode 7 is on the right side in FIG. 1, positions of the source electrode 6 and the drain electrode 7 are not unalterable, mutual substitution is possible as an example. The source electrode 6 and the drain electrode 7 can be formed by any proper conductive material, such as metal based on Al, metal based on Ag, metal based on Cu, metal based on Mo, metal based on Cr, metal based on Ta, metal based on Ti. For instance, the source electrode 6 and the drain electrode 7 can be multilayer structures such as Mo/Al/Mo, Mo/Al, Mo/Cu, CuMn/Cu and Ti/Cu without limitation. A thickness of the source electrode 6 or the drain electrode 7 can be in a range of 200˜6000 angstroms. The source electrode 6 and the drain electrode 7 can have a pattern for example formed by a photo process or an etching process.

The TFT according to the exemplary embodiment of the disclosure can further include a passivation layer 8. The passivation layer 8 can cover the semiconductor layer 4, the pixel electrode 5, the source electrode 6, and the drain electrode 7. The passivation layer 8 can be formed by for example a PECVD process. The passivation layer 8 can be a single-layer or multilayer structure including any proper material such as SiOₓ, SiNₓ, SiON. Optionally, a contact surface of the passivation layer 8 and the semiconductor layer 4 can be oxygen-enriched SiOₓ. A thickness of the passivation layer 8 can be in a range of 1500˜4000 angstroms.

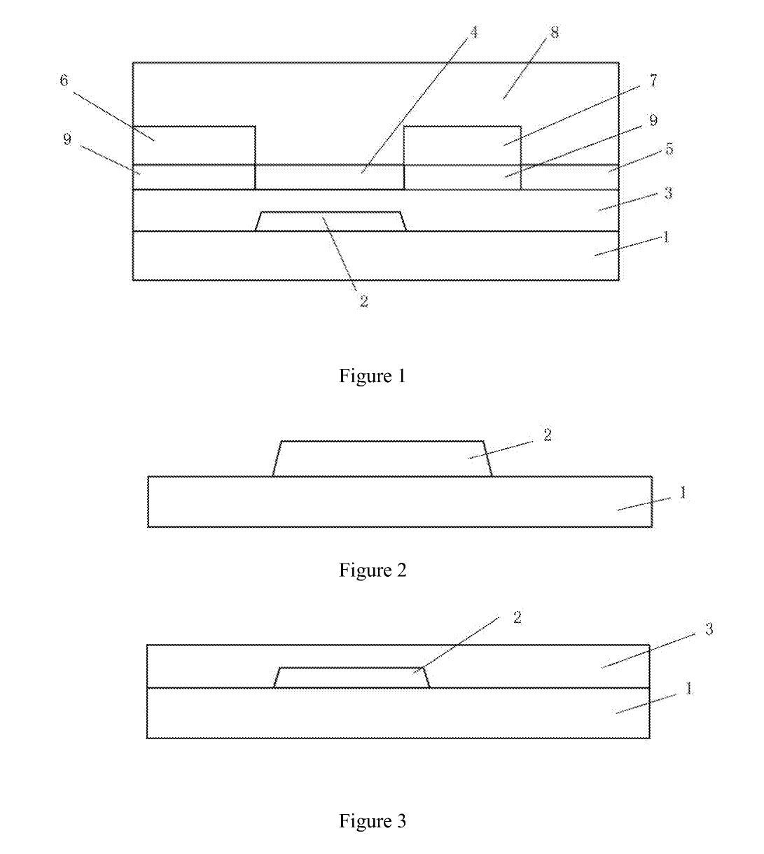

FIG. 2 through FIG. 7 are referred to describe a method of manufacturing a TFT according to an exemplary embodiment of the disclosure in detail as follows.

FIG. 2 through FIG. 7 show cross-sectional views of a method of manufacturing the TFT shown in FIG. 1 according to an exemplary embodiment of the disclosure.

The method of manufacturing the TFT according to the exemplary embodiment of the disclosure can include: forming the gate electrode 2 on the substrate 1 (S1); forming the gate insulating layer 3 on the gate electrode 2 (S2); forming the semiconductor layer 4 on the gate insulating layer 3 (S3); irradiating light with a predetermined wavelength from the back, making a section of the semiconductor layer 4 that is not covered by the gate electrode to be the pixel electrode 5 and the ohmic contact layers 9, and a section of the semiconductor layer 4 covered by the gate electrode retains a semiconductor characteristic (S4); forming the source electrode 6 and the drain electrode 7 on the pixel electrode 5 and the ohmic contact layers 9 (SS).

As shown in FIG. 2, in step S1, the gate electrode 2 can be formed on the substrate 1 by a proper method, then the gate electrode 2 is patterned by a photo process or an etching process as examples. For instance, the gate electrode 2 can be deposited by a PVD or CVD process. The gate electrode 2 can be formed by metal and/or metal alloy. For instance, the gate electrode 2 can be made out of metal based on aluminum, metal based on silver, metal based on copper, metal based on molybdenum, metal based on chromium, metal based on tantalum, metal based on titanium. Optionally, the gate electrode 2 can include a multilayer structure, such as at least two conductive layers with different physical properties. For instance, the gate electrode 2 can be a multilayer structure of Mo/Al/Mo, Mo/Al, Mo/Cu, CuMn/Cu and Ti/Cu. Optionally, a buffer layer (not labelled) can be formed on the substrate 1, then the gate electrode 2 is formed on the buffer layer. A thickness of the gate electrode 2 can be in a range of 2000˜5500 angstroms.

Referring to FIG. 3, in step S2, the gate insulating layer 3 is formed on the gate electrode 2 to cover the gate electrode 2. The gate insulating layer 3 can be formed by any proper method such as PECVD. A thickness of the gate insulating layer 3 can be in a range of 1500˜4000 angstroms. The gate insulating layer 3 can be a single-layer or multilayer structure including any proper insulating material such as SiOₓ, SiNₓ, SiON.

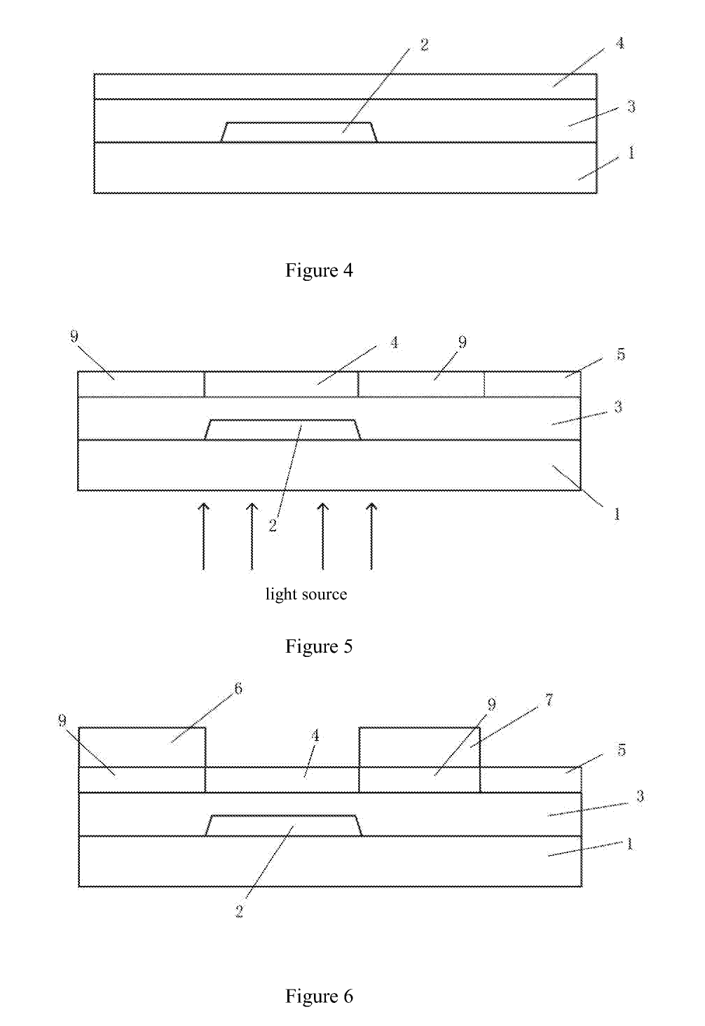

Referring to FIG. 4, in step S3, the semiconductor layer 4 is formed on the gate insulating layer 3. The semiconductor layer 4 can be deposited by any proper method such as PVD. The semiconductor layer 4 can be patterned for example by a photo process or an etching process. The semiconductor layer 4 can have a pattern insulating from the source electrode 6 to be formed and connected to the drain electrode 7 to be formed by patterning, therefore, it is unnecessary to connect the pixel electrode 5 and the source electrode 6 by a through-hole.

Furthermore, the semiconductor layer 4 can be formed by oxide semiconductor. For instance, oxide semiconductor can include any proper metal (i.e. Zn, In, Ga, Sn, Ti) or any proper metal alloy oxide. Optionally, the semiconductor layer 4 can be formed by IGZO. A thickness of the semiconductor layer 4 can be in a range of 400˜1500 angstroms.

Referring to FIG. 5, in step S4, irradiating light with a predetermined wavelength from the back, making a section of the semiconductor layer 4 that is not covered by the gate electrode 2 to be the pixel electrode 5 and the ohmic contact layers 9, and a section of the semiconductor layer 4 covered by the gate electrode 2 retains a semiconductor characteristic, in order to form the pixel electrode 5 and the ohmic contact layers 9 on the same layer with the semiconductor layer 4. According to the exemplary embodiment of the disclosure, a range of the predetermined wavelength can be 110 nm˜760 nm. Optionally, the range of the predetermined wavelength can be 110 nm˜400 nm, 150 nm˜700 nm or 200 nm˜450 nm. Preferably, the light applied to irradiate can be ultraviolet light (UV). Optionally, the light applied to irradiate can be visible light. According to the exemplary embodiment of the disclosure, time for irradiating can be 1˜6 hours, for instance, around 4 hours. The time is shorter along with longer wavelengths to irradiate.

According to the exemplary embodiment of the disclosure, carrier concentration and Hall mobility of oxide semiconductor such as IGZO can be increased by irradiating, and electric conductivity is improved, making a section of the semiconductor layer 4 that is not covered by the gate electrode 2 to be the pixel electrode 5 and the ohmic contact layers 9, and a section of the semiconductor layer 4 covered by the gate electrode 2 retains a semiconductor characteristic. In other words, the gate electrode 2 as a light shield layer prevents light from irradiating on the semiconductor layer 4. According to the exemplary embodiment of the disclosure, under the circumstances that the semiconductor layer 4 is formed by IGZO, after being irradiated by UV light, the electric conductivity is increased by 10⁹, Hall mobility can be 14.6 cm²/V, carrier concentration is around 1.6×10¹³ cm⁻², resistance is around 4.6×10⁻³ Ω·cm, thereby requirements of the pixel electrode can be fulfilled. After 4 weeks of aging test (in the atmosphere), electrical properties are almost the same, which mean irradiating UV light causes irreversible transformation.

According to the exemplary embodiment of the disclosure, the semiconductor layer 4 can be activated by being annealed at 100˜400° C. after being irradiated, which can reduce flaws.

As shown in FIG. 6, in step S5, the source electrode 6 and the drain electrode 7 can be formed on the pixel electrode 5 and the ohmic contact layers 9. According to the exemplary embodiment of the disclosure, the source electrode 6 and the drain electrode 7 can be formed on the ohmic contact layers 9 adjacent to two ends of the semiconductor layer 4. For instance, the source electrode 6 can be formed on the ohmic contact layer 9 on left side of the semiconductor layer 4, the drain electrode 7 can be formed on the ohmic contact layer 9 on right side of the semiconductor layer 4. The pixel electrode 5 can be connected to the drain electrode 7 by the ohmic contact layer 9 below the drain electrode 7. The ohmic contact layer 9 below the drain electrode 7 can be connected to the semiconductor layer 4. The pixel electrode 5 and the source electrode 6 can be insulated.

The source electrode 6 and the drain electrode 7 can be formed by any proper conductive material, such as metal based on Al, metal based on Ag, metal based on Cu, metal based on Mo, metal based on Cr, metal based on Ta, metal based on Ti. For instance, the source electrode 6 and the drain electrode 7 can be multilayer structures such as Mo/Al/Mo, Mo/Al, Mo/Cu, CuMn/Cu and Ti/Cu without limitation. The source electrode 6 and the drain electrode 7 can be patterned for example by a photo process or an etching process. A thickness of the source electrode 6 or the drain electrode 7 can be in a range of 200˜6000 angstroms.

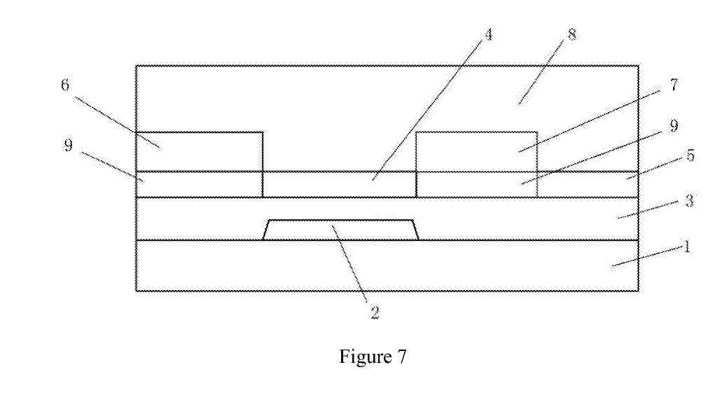

As shown in FIG. 7, the method of manufacturing a TFT according to the exemplary embodiment of the disclosure can further include forming the passivation layer 8 (S6). The passivation layer 8 can cover the semiconductor layer 4, the pixel electrode 5, the source electrode 6 and the drain electrode 7. The passivation layer 8 can be formed by for example a PECVD process. The passivation layer 8 can be a single-layer or multilayer structure including any proper material such as SiOₓ, SiNₓ, SiON. Optionally, a contact surface of the passivation layer 8 and the semiconductor layer 4 can be oxygen-enriched SiOₓ. A thickness of the passivation layer 8 can be in a range of 1500˜4000 angstroms.

According to the TFT and the manufacture method thereof of the exemplary embodiments of the disclosure, the pixel electrode and the semiconductor layer are formed on the same layer, compared with a conventional technique that two separate masks are needed to form a semiconductor layer and a pixel electrode respectively, the disclosure employs one mask to produce the semiconductor layer and the pixel electrode, which can reduce mask consumption and processes.

Above are exemplary embodiments of the disclosure, it is comprehensible to a person skilled in the art that any modifications, equivalent replacements or improvements within the spirit and principles of the embodiments described above should be covered by the protected scope of the disclosure.

What is claimed is:

1. A thin film transistor, wherein the thin film transistor comprises:
a substrate;
a gate electrode, formed on the substrate;
a gate insulating layer, formed on the gate electrode;
a semiconductor layer, formed on the gate insulating layer and corresponding to the gate electrode;
a pixel electrode, disposed on the same layer with the semiconductor layer;
an ohmic contact layer, formed on the same layer with the semiconductor layer and formed on the same layer with the pixel electrode;
a source electrode and a drain electrode, disposed on the ohmic contact layer.

2. The thin film transistor according to claim 1, wherein the pixel electrode and the drain electrode are connected by the ohmic contact layer below the drain electrode.

3. The thin film transistor according to claim 2, wherein the ohmic contact layer below the drain electrode and the semiconductor layer are connected.

4. The thin film transistor according to claim 1, wherein the gate electrode is formed by metal and/or metal alloy, the semiconductor layer is formed by oxide semiconductor.

5. A method of manufacturing a thin film transistor, wherein the method comprises:
forming a gate electrode on a substrate;
forming a gate insulating layer on the gate electrode;
forming a semiconductor layer on the gate insulating layer;
irradiating light with a predetermined wavelength from the back, making a section of the semiconductor layer that is not covered by the gate electrode to be a pixel electrode and an ohmic contact layer, and a section of the semiconductor layer covered by the gate electrode retaining a semiconductor characteristic;
forming a source electrode and a drain electrode on the pixel electrode and the ohmic contact layer.

6. The method according to claim 5, wherein a range of the predetermined wavelength is 110 nm˜760 nm.

7. The method according to claim 5, wherein the light is ultraviolet light.

8. The method according to claim 5, wherein the gate electrode is formed by metal and/or metal alloy, the semiconductor layer is formed by oxide semiconductor.

9. The method according to claim 5, wherein the pixel electrode and the drain electrode are connected by the ohmic contact layer below the drain electrode.

10. The method according to claim 5, wherein the ohmic contact layer below the drain electrode and the semiconductor layer are connected.
